(19) United States
(12) Patent Application Publication
(10) Pub. No.: US 2005/0078447 A1
(43) Pub. Date: Apr. 14, 2005

(54) Method and apparatus for improving power efficiencies of computer systems

(75) Inventors: Hendrik F. Hamann, Yorktown Heights, NY (US); Theodore G. van Kessel, Millbrook, NY (US); Robert Jacob von Gutfeld, New York, NY (US)

Correspondence Address: MCGINN & GIBB, PLLC, 8321 OLD COURTHOUSE ROAD, SUITE 200, VIENNA, VA, 22182-3817, US

(73) Assignee: International Business Machines Corporation, Armonk, NY (US)

(21) Appl. No.: 10/680,233

(22) Filed: Oct. 8, 2003

(51) Int. Cl. H05K 7/20

(52) U.S. Cl. 361/689; 361/697; 165/104.33; 174/15.2; 165/80.3

(57) ABSTRACT

An assembly (and method) including at least one microprocessor, includes a mechanism for recycling heat generated by at least one microprocessor to energy, and a mechanism for directing the heat from the at least one microprocessor to the mechanism for recycling heat. The energy generated by the mechanism for recycling the heat can be used to cool the at least one microprocessor or to supply an electric power grid.

### CROSS-REFERENCE TO RELATED APPLICATION

The present application is related to U.S. patent application Ser. No. ______, filed on ______, to Robert Jacob von Gutfeld, entitled “APPARATUS AND METHOD FOR UTILIZING RECIRCULATED HEAT TO CAUSE REFRIGERATION” having IBM Docket No. YOR920030071US1, assigned to the present assignee, and incorporated herein by reference.

### BACKGROUND OF THE INVENTION

1. Field of the Invention

The present invention generally relates to a method and an apparatus suitable for improving the power efficiencies of computer systems.

2. Description of the Related Art

For the year 2004, it is projected that more than ˜5% of the total power needed in the U.S. is consumed just alone in data centers, which is typically realized by large assemblies of mainframe computers and data storage systems.

More specifically, an IBM mainframe computer system requires ˜(20-30) kW (excluding any additional power consumption due to air conditioning etc.). Approximately half of the power is used in the processors (e.g., microprocessors). With ˜10 cents per kWh, each mainframe computer results in more than $10K of utility costs per year, which represents a significant fraction of the total costs to run a mainframe computer. In the future, these utility costs for computer systems are projected to rise even higher as processors become more powerful and as device dimensions in microprocessor decrease.

A conventional system 100 for cooling computer chips is illustrated in FIG. 1A. Heat (e.g., at about 50° C.), is removed from a computer chip (e.g., a microprocessor) 110 typically by solid state conduction via a cooling unit 120. The cooling unit 120 may cool the chip to about 20° C.

For example, the chip 110 is in contact with the cooling unit 120 (e.g., such as a Cu heat sink with fins) via a thermal interface material (e.g., thermal paste or oil). The heat sink 120 then spreads the heat over a large area, and a fan (not illustrated in FIG. 1A) removes the heat from the fins blowing it into the air. The energy Wₑₓ for driving the fan is obtained from an external source, thereby adding even more to the power consumption of the computer system.

The fraction of the utility costs is increasing to a prohibitive level, as time progresses. Hence, more and more of the costs for operating a data center will have to be dedicated to the utility costs. Indeed, the need for power is expected to grow so large that conceivably an entire, dedicated power plant may be needed to operate and meet the data center's electrical needs since there may not be enough power locally to meet the data center's power requirements. Thus, not only will there be an increase in day-to-day current needs, but also a large potential infrastructure cost may be expected.

### SUMMARY OF THE INVENTION

In view of the foregoing and other exemplary problems, drawbacks, and disadvantages of the conventional methods and structures, an exemplary feature of the present invention is to provide a method and structure for suitably improving the power efficiencies of computer systems.

In a first exemplary aspect of the present invention, an assembly (and method) including at least one microprocessor, includes means for recycling the heat generated by at least one microprocessor to energy, and means for directing the heat from the microprocessor to the means for recycling heat. The recycled energy can be used for cooling the microprocessor and/or be used for supplying an electric power grid. In both cases, the overall power efficiency of the computer system is improved.

With the unique and unobvious aspects of the present invention, the invention recognizes that a significant fraction of the total power is consumed by only a few computer chips (e.g., microprocessors). Further, the power density in these computer chips is remarkably high, and thus can be readily directed towards a heat engine without significant thermal loading of the microprocessor. Additionally, it is realized that at least some of the heat can be recycled to lower the overall power consumption of computer systems.

### BRIEF DESCRIPTION OF THE DRAWINGS

The foregoing and other exemplary purposes, aspects and advantages will be better understood from the following detailed description of an exemplary embodiment of the invention with reference to the drawings, in which:

FIG. 1A illustrates a conventional cooling system 100;

FIG. 1B illustrates a system 130 the present invention, wherein the heat is directed towards a heat engine 160 (e.g., means for recycling heat to energy);

FIG. 1C illustrates a more specific embodiment of a system 150 according to the present invention, wherein the energy generated by a heat engine 160 (e.g., means for recycling heat) is used for cooling a microprocessor 110;

FIG. 2A illustrates a means 200 for directing heat by solid state heat conduction, which can be part of a heat sink 204 from at least one microprocessor 202 to a hot reservoir 206 of a heat engine;

FIG. 2B illustrates a means 210 for directing heat by flowing a medium directly through at least one microprocessor 216 to a hot reservoir 218 of a heat engine;

FIG. 2C illustrates a means 220 for directing heat by flowing a medium directly over an upper surface of the at least one microprocessor 224 to a hot reservoir 226 of a heat engine;

FIG. 2D illustrates a means 230 for directing heat by flowing a medium through an opening in a heat sink 234 over the at least one microprocessor 238 to a hot reservoir 240 of a heat engine;

FIG. 2E illustrates a means 250 for directing heat using a heat pipe 252 from at least one microprocessor 254 to a hot reservoir 256 of a heat engine;

FIG. 2F illustrates another means 260 for directing heat using the hot air, which is blown by a fan 266 towards the hot reservoir of a heat engine;

FIG. 2G illustrates another means 280 for directing heat towards means for recycling heat to energy having a thermoelectric circuit 282 and thermal paste 284 directly in thermal communication with at least one microprocessor 286;

FIG. 3 illustrates a first exemplary embodiment 400 according to the present invention utilizing a thermoelectric circuit for heat recovery;

FIG. 4 illustrates a second embodiment 450 according to the present invention; and

FIG. 5 illustrates a method 500 according to the present invention which utilizes a displacer-type Stirling engine.

### DETAILED DESCRIPTION OF EXEMPLARY EMBODIMENTS OF THE INVENTION

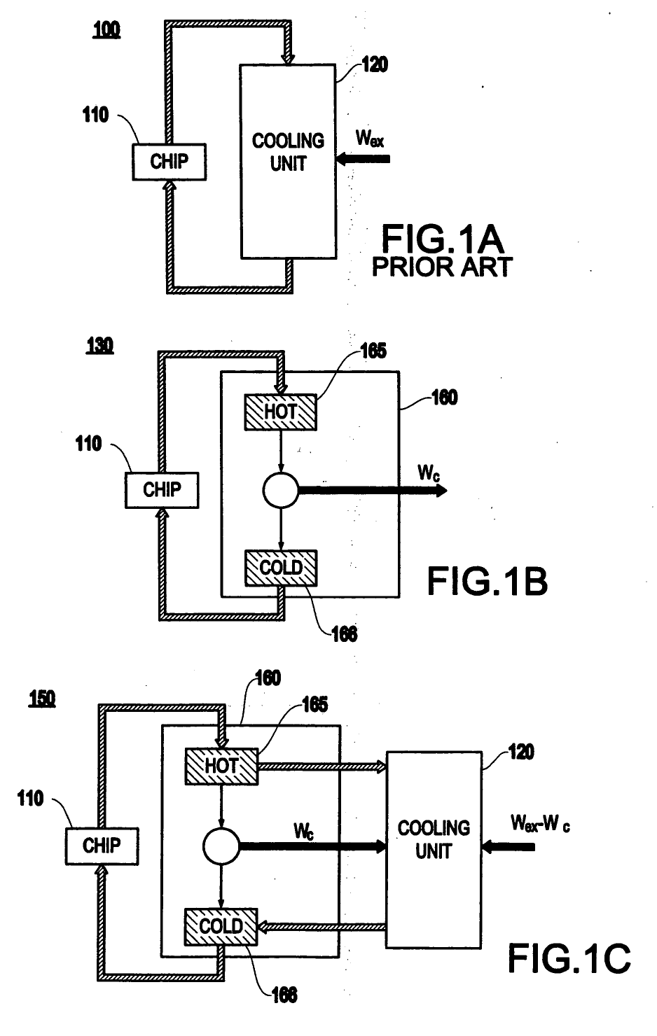

Referring now to the drawings, and more particularly to FIGS. 1A-5, there are shown exemplary embodiments of the method and structures according to the present invention.

Exemplary Embodiment

Hereinbelow, an exemplary structure of a Carnot heat engine is used according to the present invention.

By way of contrast to the conventional system 100 shown in FIG. 1A, the present invention realizes that: 1) a significant fraction of the total power is consumed by only a few computer chips (e.g., microprocessors); 2) the power density in these computer chips is remarkably high and thus can be readily directed towards a heat engine without thermally loading the computer chips; and 3) at least some of the heat can be recycled to lower the overall power consumption of computer systems.

FIG. 1B illustrates one basic aspect of a system 130 of the present invention. The heat from at least one microprocessor 110 is directed towards means for recycling heat to energy (in this example a heat engine 160 having hot and cold reservoirs 165, 166, respectively). The energy Wc can be used for other purposes, which lowers the overall power consumption of the computer systems. For example, the energy Wc can be used to drive a generator producing electric energy, which is fed back into an electrical power grid. In other cases, the energy Wc can be used to drive a fan or other cooling mechanisms.

A little more specific aspect of the present invention is illustrated in a system 150 shown in FIG. 1C, wherein the energy, which is recovered by a heat engine 160 is used to provide cooling for the same microprocessor 110, which drives the heat engine 160. This heat engine 160 recycles the heat (e.g., at about 50° C.), back to work W_{c} (e.g., W_{carnot}), which can be used, for example, to cool the chip 110 (e.g., to about 20° C.). Consequently, less external work Wₑₓ is needed to cool the computer chip 110, thereby resulting in less power consumption for the computer system. The present invention also realizes that the assembly of FIG. 1C may provide a feedback system, where the chip is more cooled as it runs hotter, thereby resulting in a steady temperature.

More specifically, in FIG. 1B and FIG. 1C, the heat from the chip 110 is directed towards the hot reservoir 165 of the heat engine 160 (e.g., a Carnot-type heat engine). For example, a medium (e.g., water, but of course the invention is not limited to such a medium and may employ air, a gas such as nitrogen, etc.) may be fed into the hot reservoir 165 of the heat engine 160.

The heat engine 160 recycles the heat with some finite efficiency back to work W_{c}, which is used to cool the water (e.g., it may be used to drive a fan) in the cooling unit 120. The cooling water cools the chip, and is fed into the cold reservoir 166 of the heat engine 160, and then finally back to the chip 110. Using a Carnot cycle, the present inventors have found that the efficiency of converting the heat into work can be estimated, which results in ˜10% savings for the temperatures described above with regard to FIG. 1C as an upper limit.

A 10% power saving could result into about $1000 savings per year per mainframe. For example, typical data centers include about 1000 mainframe computers, which results in additional power saving costs of about 1 million dollars per year. Since the heat recovery in a data center can be realized by one heat engine, the present invention should lead to significant savings even after subtracting the costs of the heat engine.

Generally, and as described in further detail below, the present invention provides an assembly which includes at least one microprocessor, means for directing heat, and means for recycling the heat.

Additionally, the invention provides a method which includes providing an assembly which includes at least one microprocessor, means for directing heat, and means for recycling the heat.

Generally, the heat of any computer chip can be used in the present invention. However, in most cases, most of the power in a computer system is dissipated in the processor chips. As an example, such a computer chip may comprise IBM's PowerPC® processor (Power4, Power5), or Intel's Pentium®, Xenon®, Itanium® processors or AMD's Athalon®, Operon® microprocessor. Besides the processor chip, graphic chips may use a significant fraction of the power.

Regarding the means for directing the heat in order to recycle the heat to energy, fundamentally, the design of this mechanism (means) should consider several parameters.

First, it is desirable that the computer chip is hot, so that the recycling efficiency can be improved. On the other hand, it is required that the computer chip does not get hotter than specified in order to protect the computer chip circuit. Both of these requirements result in one common requirement for the mechanism (means) for directing heat towards recycling.

Specifically and ideally, there should be a minimum temperature difference between the computer chip (e.g., microprocessor) and, for example, the hot reservoir of the heat engine. For example, a preferred range of temperature differences is between about 1° C. to about 20° C., and more preferably less than 1° C.

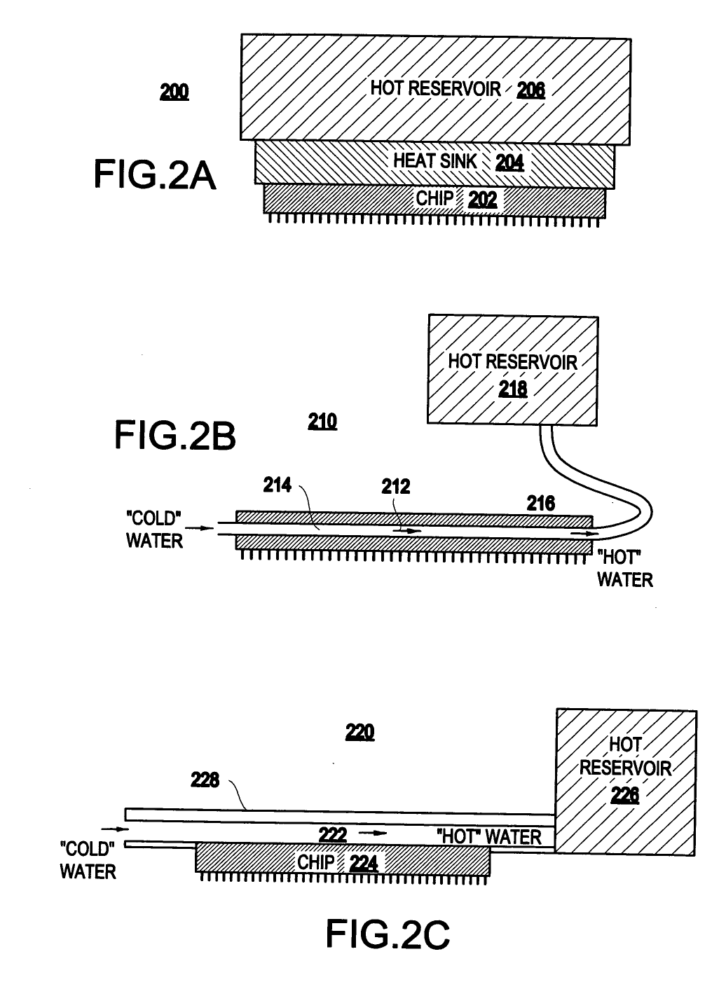

Even more ideally, the heat removed by recycling should result in an acceptable steady state temperature of the chip. Typically, this can be achieved if the energy, which is generated by the means for recycling the heat, is used to cool the computer chip, such as illustrated in FIG. 1C. In principle, all different ways of heat conduction can be used to direct the heat from the computer chip to the means of recycling the heat, which will be in most cases a heat engine. Hereinbelow are discussed a few exemplary, non-limiting structures of the mechanism (means) for directing heat with reference to FIGS. 2A-2D.

Turning to an exemplary structure 200 of FIG. 2A for showing means for directing the heat, a computer chip 202 is in good thermal contact with a heat sink 204. The heat sink 204 is preferably a good thermal conductor such as a solid piece of metal such as Cu or the like.

The metal block 204 conducts the heat from the chip 202 to the hot reservoir 206 of a heat engine. In practice, the “boundaries” between the chip 202, the illustrative metal block 204 and the hot reservoir 206 can limit the heat transfer significantly. As a result, there can be a large temperature drop (e.g., in a range between about 20° C. to about 50° C.) between the chip 202 and the hot reservoir 206, which may not be desired.

Specifically, for improving the efficiency of the heat engine, the largest possible temperature in the reservoir 206 is desired. At the same time, the chip 202 temperature cannot be above certain specifications, otherwise damage to the chip potentially occurs.

Consequently, in order to improve the heat transfer from the chip 202 to the hot reservoir 206, interface materials such as thin oils or thermal paste may be used. Thermal pastes typically include of an oil or fat amalgamated with metals or metal oxides. The paste may be formed between the chip 202 and the heat sink 204 and/or the heat sink 204 and the hot reservoir 206. It is preferred that these pastes are as thin as possible (e.g., typically less than 4 mils).

In other situations, it may be preferred to bond chemically the heat sink 204 to the chip 202. For example, a thin Au layer between an illustrative metal (e.g., Cu) block 204 and the Si-chip 202 can be used to bond at high temperatures (e.g., within a range of about 300° C. to about 500° C.). Yet another way of improving the thermal transfer from the chip 202 to the hot reservoir 206 may comprise using silver epoxy or solder. Specifically, these materials would be positioned between the heat sink and the hot reservoir.

FIGS. 2B-2D show other exemplary means for directing the heat.

For example, while in FIG. 2A the heat is directed via solid state conduction towards the means for recycling heating, FIGS. 2B-2D use mass transport (e.g., a flow of water) to direct the heat from the chip to the hot reservoir of an illustrative heat engine.

In FIG. 2B, the structure 210 is shown in which water 212 is pumped directly through openings 214 in the Si-chip 216. Water first enters the chip cold, then it is heated by the high power dissipation in the chip 216, and finally is fed into a hot reservoir 218. The openings 214 in the Si-chip 216 may comprise a flow channel.

In FIG. 2C, a structure 220 is shown in which water 222 flows directly over a chip 224, and then fed into a hot reservoir 226. A cover and tubing structure 228 may be positioned close the chip 224 in order to enhance the heat transfer coefficient. In some cases, it may be preferred to coat the Si chip 224 for protecting the embedded circuit tree. For example, the chip could be coated with a Nickel film (i.e., a material that does not diffuse into the Si) in a thickness of about 50 Å to about 1000 Å.

In yet another variation of the present invention, as shown in a structure 230 illustrated in FIG. 2D, water 232 flows through openings 234 of a heat sink 236 such as a metal (e.g., Cu) block. A heat sink 236 preferably is in direct thermal contact, preferably using interface materials such as thermal paste or thermal oils with a microprocessor chip 238 (e.g., a Si chip). Then, the water is used to heat a hot reservoir 240, for example, of a heat engine.

In FIG. 2E, a structure 250 is shown in which heat pipes 252 are used to transfer the heat from the Si-chip 254 to the hot reservoir 256.

The heat pipe 252 can be a separate piece (e.g., separate from the chip 254 and hot reservoir 256) with the evaporation zone relatively closer to the chip 254 and the condensation zone relatively closer to the hot reservoir. If the heat pipe 252 is separate from the chip 254, then good thermal contact between heat pipe 252 and chip 254 is required. Since for the exemplary application of increasing power efficiency of computer systems, it is desired to have a predetermined small temperature drop between the hot reservoir and the chip, but still not to overheat the chip, the heat fluid should be chosen appropriately. It is noted that such a temperature range is a “moving target” (e.g., cannot be stated with great specificity), since it depends on the designer's requirements etc. Again, if the temperatures are higher, the efficiency will be greater, but at the expense of potentially damaging the chip. Hence, a tradeoff should be made depending upon the designer's requirements.

FIG. 2F illustrates another possible means to direct the heat from the microprocessor to an illustrative hot reservoir of a heat engine using convection.

Specifically, a structure 260 is shown in which a chip 262 is in good thermal contact with a heat sink 264, preferably using interface materials such as paste and oil (not shown) between the chip 262 and the heat sink 264. The heat sink 264 is preferably metal, and more preferably Cu because of its high thermal conductivity. The heat sink 264 preferably may have fins in order to distribute the heat over a larger area. A fan 266 blows air through the fins towards the hot reservoir of the heat engine 268. In some cases, it may be preferred to use a duct or channel 270 in order to direct the hot air flow.

In cases where the recycling is realized by thermoelectric effects, thin film thermocouples could be patterned directly onto the chip, onto a heat sink or embedded in paste, as illustrated in the structure 280 of FIG. 2G.

In FIG. 2G, a thin sheet (e.g., preferably having a thickness between about 10 microns to about 200 microns) of thermocouples 282 for heat recovery is sandwiched in the thermal paste 284, which interfaces the chip 286 with a heat sink 288.

Turning now to a means for energy-recycling of the heat, generally, any kind of heat recovery can be used. As one example, the heat from the chip can drive a chemical reaction, which is used to store energy. In addition, thermoelectric heat recovery may be considered where the recycling unit may include arrays of thermocouples.

However, in most cases, a heat engine is preferred. A generic discussion about heat engines can be found, for example, in Thermodynamics by Y. A. Cengel and M. A. Boles, McGraw-Hill, New York (2002). The heat engine can be, for example, realized by a Stirling or Ericsson engine, which can have efficiencies close to the ideal Carnot cycle. In addition, gas turbine engines may be considered.

A Carnot heat engine cycle includes four reversible steps during which heat is converted to work with some efficiency. A simple Carnot heat engine can be realized by a cylinder with a piston and a working gas as well as two reservoirs: one cold reservoir and one hot reservoir.

First, in a first step, the illustrative cylinder is brought in contact with the hot reservoir (which is heated by the heat from the chip in the present invention). The working gas expands and the piston is generating work, thereby recycling the heat to energy. As the gas expands, the temperature of the gas tends to fall, but the hot reservoir (e.g., heated by the heat from the chip) transfers energy to the working gas maintaining its temperature at T_{H}.

In a second step, the hot reservoir is removed from the cylinder so that the system becomes adiabatic. The gas continues to do work on the surrounding. However, now the gas temperature drops to T_{C}.

In a third step, the cylinder is now brought in contact with the cold reservoir (at T_{C}). The piston is pushed inwardly by an external force doing work on the gas. As the gas is compressed, its temperature tends to rise, but heat flows from the working gas to the cold reservoir maintaining the temperature of the working gas at T_{C}.

Finally, in a fourth step, the cold reservoir is removed from the cylinder, and the gas is compressed further during which the temperature is increased back to T_{H}.

In contrast, the Stirling cycle replaces the two adiabatic processes (i.e., step 2 and 4) of the Carnot cycle by two constant volume regeneration processes, while the Ericsson cycle uses two constant pressure regeneration processes.

Both cycles (e.g., Stirling and Ericsson) use regeneration. Energy is stored during one part of the cycle and transferred back during another part of the cycle. The classical Stirling engine is typically constructed in two forms: a two-piston arrangement, and a displacer-type, both of which are well-known to those ordinarily skilled in the art, and thus for brevity will not be further discussed herein.

Another variation of a heat engine comprises a thermoacoustic Stirling heat engine (S. Backhaus, G. W. Swift, Nature 399, 335 (1999)), which has no moving parts.

This heat engine is based on gas in an acoustic traveling wave propagating through a regenerative heat exchanger undergoing a thermodynamic cycle, which is similar to the “ideal” Stirling cycle. This type of engine exploits that oscillations of pressure and volumetric velocity are temporally in phase in a traveling wave.

Such a thermoacoustic heat engine includes, for example, a ¼-wavelength acoustic resonator filled with a gas (e.g., helium) at some higher pressure (˜30 atm), heat exchangers and a regenerator. Further, this engine contains inertance due to the inertia of the helium, and compliance due to the compressibility of helium, both of which are necessary to force the working gas to undergo a Stirling engine.

Besides Stirling and Ericsson heat engines, gas turbine engines (e.g., Brayton type) can be generally used as well, which may comprise two heat exchangers (one for the cold reservoir and one for the hot reservoir), a turbine and a compressor.

Finally, the present invention also considers thermoelectric heat recovery. Although thermoelectric heat recovery efficiencies are substantially below the Carnot limit, they are simply integrated.

The thermoelectric heat recovery unit may comprise an array of thermocouples in parallel and/or series. The thermocouple may include materials with a large Seebeck coefficient such as semi-conducting materials and Bismuth Telluride. Further the thermoelectric heat recovery unit may comprise p-n junctions.

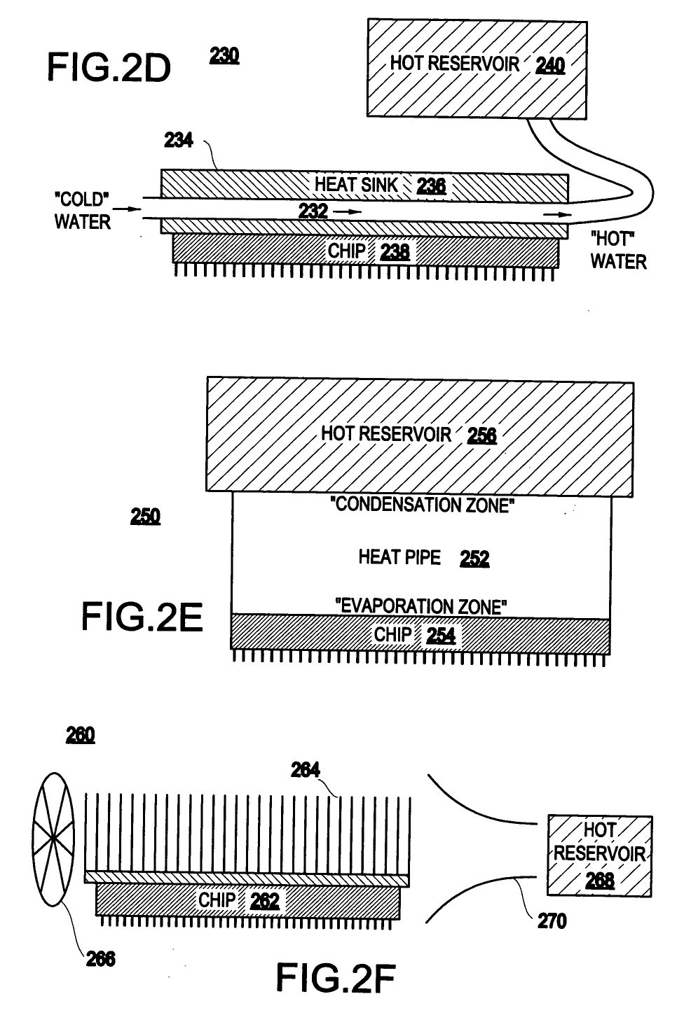

Turning now to FIG. 3, an exemplary embodiment of a system 400 according to the present invention is illustrated.

System 400 includes, for the heat recovery, a thermoelectric circuit including arrays of thermocouples 482. The thermocouple array 482 is preferably patterned directly on a chip 486. In other situations, it may be preferred to use the Si-chip 486 or part of the Si-chip 486 as part of the thermoelectric circuit 482. Fan 490 may be provided for blowing air over the fins of the heat sink. Thermal paste 484 may preferably used to realize a the thermal coupling between the chip and the thermoelectric module 482.

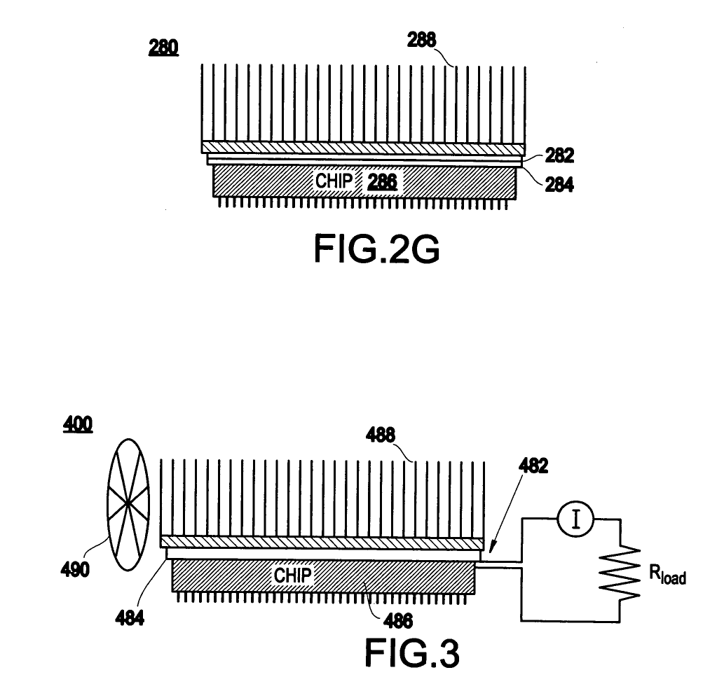

FIG. 4 shows a basic form of a displacer-type Stirling engine 450, which may comprise a two-piston-type engine.

First, a working gas is heated, which expands. The gas below the displacer piston 420 is hotter than the gas above the displacer piston 420, which moves the displacer piston 420 upwardly. The displacer piston 420 displaces the gas, and increases the pressure in the chamber. When the engine 410 is at high pressure, the power piston 430 moves upwardly, thereby turning a crank (unreferenced) and releasing the pressure and cooling the gas. When the gas is cooled, the displacer piston 420 moves downwardly. In FIG. 4, the Stirling engine 450 is in good thermal contact with the chip 496 using a thermal paste 440. Adjacent the displacer piston 420 are the hot reservoir 406 and the cold reservoir 407.

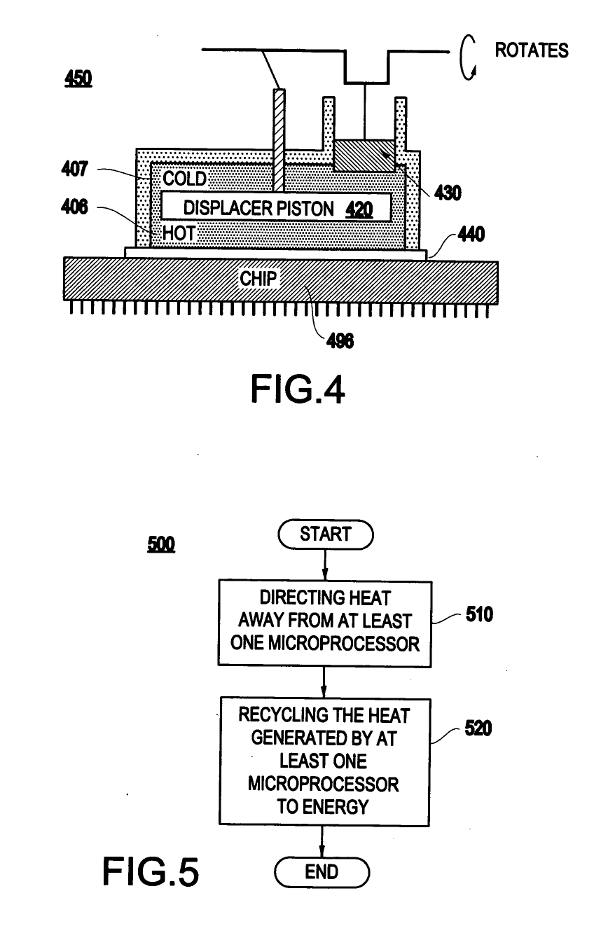

FIG. 5 illustrates a method 500 according to the invention for improving the power efficiency of a computer system including at least one microprocessor.

Specifically, in step 510, the heat is directed away from at least one microprocessor. Then, in step 520, the heat generated by the at least one microprocessor is recycled into energy.

As described above, with the unique and unobvious aspects of the present invention, the invention recognizes that a significant fraction of the total power is consumed by only a few computer chips (e.g., microprocessors). Further, with the invention, the power density in these computer chips is remarkably high, and thus can be readily directed towards means for recycling the heat to energy (e.g., heat engine) without thermal loading. Additionally, at least some of the heat can be recycled to lower the overall power consumption of computer systems.

While the invention has been described in terms of several exemplary embodiments, those skilled in the art will recognize that the invention can be practiced with modification within the spirit and scope of the appended claims.

Further, it is noted that Applicant's intent is to encompass equivalents of all claim elements, even if amended later during prosecution.

1. An assembly including at least one microprocessor, comprising:
means for recycling heats generated by at least one microprocessor, to energy; and
means for directing the heat from said at least one microprocessor to said means for recycling heat,
wherein said energy is used for cooling said at least one microprocessor.

2. (canceled)

3. The assembly of claim 1, wherein said energy is used to supply an electric power grid.

4. The assembly of claim 1, wherein said means for recycling heat comprises a heat engine.

5. The assembly of claim 4, wherein said heat engine comprises a Stirling heat engine.

6. The assembly of claim 4, wherein said heat engine comprises at least one of an Ericcson heat engine and a thermoacoustic heat engine.

7. The assembly of claim 1, wherein said means for recycling heat comprises a thermoelectric circuit.

8. The assembly of claim 7, wherein said thermoelectric circuit comprises an array of thermocouples.

9. The assembly of claim 1, wherein said means for recycling heat comprises a chemical reaction.

10. The assembly of claim 1, wherein said means for directing the heat comprises at least one of means for conduction, means for convection and means for mass transport.

11. The assembly of claim 1, wherein said means for directing the heat comprises a solid piece of at least one of copper, silicon, aluminum, which is in thermal contact with said at least one microprocessor.

12. The assembly of claim 1, wherein said means for directing heat comprises at least one of a thermal paste, a silver epoxy, a Au-film, a liquid metal, and an oil.

13. The assembly of claim 11, wherein said solid piece comprises a portion of a heat sink, which is used to cool said at least one microprocessor.

14. The assembly of claim 1, wherein said means for directing the heat comprises a medium flowing from said at least one microprocessor to said means for recycling heat.

15. The assembly of claim 14, wherein said medium comprises one of a gas and a liquid.

16. The assembly of claim 15, wherein said gas comprises air.

17. The assembly of claim 15, wherein said liquid comprises water.

18. The assembly of claim 1, wherein said means for directing heat comprises a flow channel.

19. The assembly of claim 1, wherein said means for directing heat comprises at least one heat pipe.

20. The assembly of claim 5, wherein said heat engine comprises:
a hot reservoir; and
a cold reservoir,
wherein the heat from said at least one microprocessor is directed by the means for directing heat via a medium to the hot reservoir of the heat engine.

21. The assembly of claim 20, further comprising a cooling unit to cool said medium.

22. The assembly of claim 21, wherein the cooled medium cools the cold reservoir of the heat engine and said at least one microprocessor.

23. The assembly of claim 21, wherein said cooling unit comprises at least one of a refrigerator, a fan, and a heat exchanger.

24. A method for use with at least one microprocessor, comprising:
directing heat away from said at least one microprocessor; and
recycling the heat generated by said at least one microprocessor to energy,
wherein said energy is used for cooling said at least one microprocessor.

25. (canceled)

26. The method of claim 24, wherein said energy is used to supply an electric power grid.

27. An assembly including at least one microprocessor, comprising:
a mechanism that recycles heat, generated by at least one microprocessor, to energy; and
a mechanism that directs heat from the at least one microprocessor, to the mechanism that recycles,
wherein said energy is used for cooling said at least one microprocessor.
